(19) United States
(12) Patent Application Publication
(10) Pub. No.: US 2006/0029162 A1
(43) Pub. Date: Feb. 9, 2006

(54) Modular multi-bit symbol demapper

(75) Inventor: Peimin Chi, Alameda, CA (US)

Correspondence Address: STMICROELECTRONICS, INC., MAIL STATION 2346, 1310 ELECTRONICS DRIVE, CARROLLTON, TX, 75006, US

(73) Assignee: STMICROELECTRONICS, INC., CARROLLTON, TX (US)

(21) Appl. No.: 10/913,773

(22) Filed: Aug. 6, 2004

(51) Int. Cl. H04L 27/06; H03M 13/03; H03D 1/00

(52) U.S. Cl. 375/340; 714/795; 375/341; 714/794

(57) ABSTRACT

A modular multiple bit symbol demapper (1000) that processes pre-detected symbol values for multiple bit symbols. A symmetry of data bit decisions around higher order data bits is used to iteratively fold, by taking an absolute value (1204, 1208) in the exemplary embodiment, pre-detected values around a lower order bit decision point and shifting (1208) the folded values in order to reduce the decision of any arbitrary bit to a BPSK decision. The ultimately reduced BPSK decision is then performed by a standard BPSK soft decision circuit (500), which can be reused for all data bits being detected. Gray coding of the multiple bit symbols allows the data bit decision produced by this processing to be directly used as decided data outputs.

### FIELD OF THE INVENTION

The present invention generally relates to signal processing associated with data communications and more particularly to signal processing to produce soft decisions for multiple bit data symbols.

### BACKGROUND OF THE INVENTION

Forward Error Correction (FEC) channel encoding is a common technique employed in communications systems to address noise and other channel impairments such as deep fading. Convolutional FEC encoding is a common channel coding practice used in communications and other data systems. A Viterbi decoder is often used to perform convolutional decoding at the receiver side. Viterbi decoders operate with either hard decision inputs or soft decision inputs. Soft decision inputs provide a measure of certainty for the detected channel bit. The additional complexity of processing soft decision inputs with a Viterbi decoder is justified by the fact that it can provide an additional 2-3 dB coding gain over the performance of a hard decision input Viterbi decoder. In the case of soft-input mode, a soft demapper is used in the receiving chain to generate the necessary inputs to feed the soft-input Viterbi.

Determining soft decisions for two-state symbols, such as for Bi-Phase Shift Keying (BPSK) symbols, is a somewhat straightforward process that can be implemented in signal processing hardware with acceptable complexity. Obtaining soft decisions with multiple level channel symbols, such as 16 and 64 symbol Quadrature Amplitude Modulation (QAM) modulation formats, requires that soft decisions be performed for each of the multiple bits conveyed by the symbol. In the case of 64 QAM symbols, for example, each of the two QAM channels conveys three data bits, for a total of six data bits. In order to realize the benefits of soft decision decoding in systems that receive 64 QAM symbols, for example, each of the six channel bits conveyed by the QAM symbol is required to have a soft decision. Signal processing hardware to determine these multiple soft decisions per symbol require more complex hardware designs that have increased design, testing, debugging and maintenance expense and management difficulties.

Therefore a need exists to overcome the problems with the prior art as discussed above.

### SUMMARY OF THE INVENTION

In accordance with an exemplary embodiment of the present invention, a method for determining soft decisions includes determining a first value representing a distance between a first bit decision point and a pre-detection value of a multiple bit symbol, the multiple bit symbol representing at least a first bit and a second bit. The method further includes determining a normalized value by shifting the first value by an amount corresponding to a second bit decision point. The method also determines an inverted second bit soft decision by processing the normalized value with a BPSK soft demapper algorithm and produces a second bit soft decision by inverting the inverted second bit soft decision value.

In accordance with another aspect of the present invention, a soft decision demapper has a first magnitude determination circuit that determines a first value representing a distance between a first bit decision point and a pre-detection value of a multiple bit symbol. The multiple bit symbol represents at least a first bit and a second bit. The soft decision demapper further has a value normalizer that determines a normalized value by shifting the first value by an amount corresponding to a second bit decision point. The soft decision demapper further has at least one BPSK soft demapper that determines an inverted second bit soft decision by processing the normalized value. The soft decision demapper also has a data inverter that produces a second bit soft decision by inverting the inverted second bit soft decision value.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 illustrates a sixty four (64) point Quadrature Amplitude Modulation (QAM) constellation as is used by an exemplary embodiment of the present invention.

FIG. 2 illustrates decision threshold points for the three data bits conveyed by one axis of the exemplary QAM64 constellation shown in FIG. 1, as is used by an exemplary embodiment of the present invention.

FIG. 3 illustrates a BPSK four-bit soft decision levels diagram as is used by an exemplary embodiment of the present invention.

FIG. 4 illustrates a dual-band BPSK soft demapper as is incorporated into the exemplary embodiment of the present invention.

FIG. 5 illustrates a BPSK soft decision circuit as is incorporated into the exemplary embodiment of the present invention.

FIG. 6 illustrates tri-band decision threshold points as are implemented by the exemplary embodiment of the present invention.

FIG. 7 illustrates a tri-band soft decision demapper according to the exemplary embodiment of the present invention.

FIG. 8 illustrates penta-band decision threshold points as are implemented by the exemplary embodiment of the present invention.

FIG. 9 illustrates a penta-band soft decision demapper according to the exemplary embodiment of the present invention.

FIG. 10 illustrates a soft decision three bit I channel data detector block diagram, according to the exemplary embodiment of the present invention.

FIG. 11 illustrates an exemplary wireless data communications device in accordance with an exemplary embodiment of the present invention.

FIG. 12 illustrates an arbitrary bit soft decision processing flow as is performed by a further exemplary embodiment of the present invention.

### DETAILED DESCRIPTION

As required, detailed embodiments of the present invention are disclosed herein; however, it is to be understood that the disclosed embodiments are merely exemplary of the invention, which can be embodied in various forms as described in the non-limiting exemplary embodiments. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

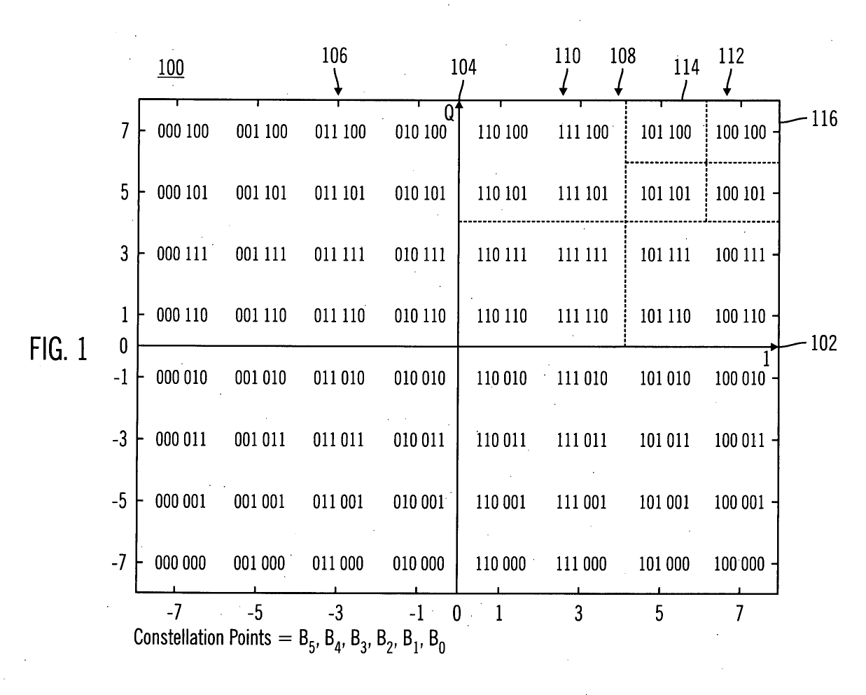

FIG. 1 illustrates a sixty four (64) point Quadrature Amplitude Modulation (QAM) constellation 100 as is used by an exemplary embodiment of the present invention. The exemplary sixty four point QAM constellation 100 illustrates sixty four possible states or values for the sixty four possible communications channel symbols used to communicate data. Since each symbol represents one of these sixty four, or 26 possible states, each symbol defined by the exemplary QAM constellation 100 is a multiple bit symbol that is able to represent one unique combination of six binary bits. The six binary bits illustrated for each constellation point in the exemplary QAM constellation 100 are shown as B₅B₄B₃B₂B₁B₀. For example, the top left constellation point illustrated with a six bit binary number equal to “000 100” has B₂ equal to “1” and the remaining bits equal to “0.” Each of the six bit binary numbers illustrated within the QAM constellation diagram indicate the particular bit combination, or bit mapping, that is associated with each particular symbol value or constellation point. As is known to ordinary practitioners of the relevant arts, a QAM signal can be resolved into two orthogonal, linear channels or axes, an In-phase channel or axis 102, denoted by the letter “I,” and a Quadrature channel or axis 104, denoted by the letter “Q.” The sixty four QAM constellation 100 illustrated in this example communicates three bits on each of these two axes.

The illustrated bit mapping for the exemplary QAM constellation 100 corresponds to the IEEE 802.11a standard for wireless communications, as provided by the Institute of Electrical and Electronic Engineers (IEEE), Piscataway, N.J. The first three bits of each illustrated constellation point indicate three bits that correspond to the position of the constellation point along the I axis 102 and the last three bits correspond to the position of the constellation point along the Q axis 104. The constellation points of the exemplary QAM constellation 100 have a bit mapping encoded with a Gray code. As is evident in the illustrated constellation bit mapping, symbols that are adjacent along either the I axis 102 or the Q axis 104 only differ by one bit, as is a well-known requirement of Gray encoding.

The three data bits conveyed along the I axis 102 are illustrated by exemplary sub-sectors of the exemplary QAM constellation 100. The three bits conveyed by the I axis 102 are represented by the leftmost bits, B₅B₄B₃, illustrated for each constellation point. A most significant bit (MSB) is represented by values along the I axis that fall either in an MSB “0” region 106 or in an MSB “1” region 108. The “0” region 106 and the “1” region 108 are separate by an I axis value of zero, indicating that negative values represent data bit “0” and positive values represent data bit “1.” The next significant data bit is represented in the right half of the constellation by a second “0” region 112 and a second “1” region 110. The next significant bit regions also form a mirror image around the “zero” point of the I axis 102, as is described in detail below. The least significant bit (LSB) conveyed on the I axis 102 is shown in the rightmost portion of the I axis as divided into an LSB “0” region 116 and an LSB “1” region 114. These regions are replicated within the second “0” region 112 and the second “1” region 110, as well as across the entire I axis 102 as is described below. It is further clear that the Q axis 104 is similarly divided to represent three additional data bits.

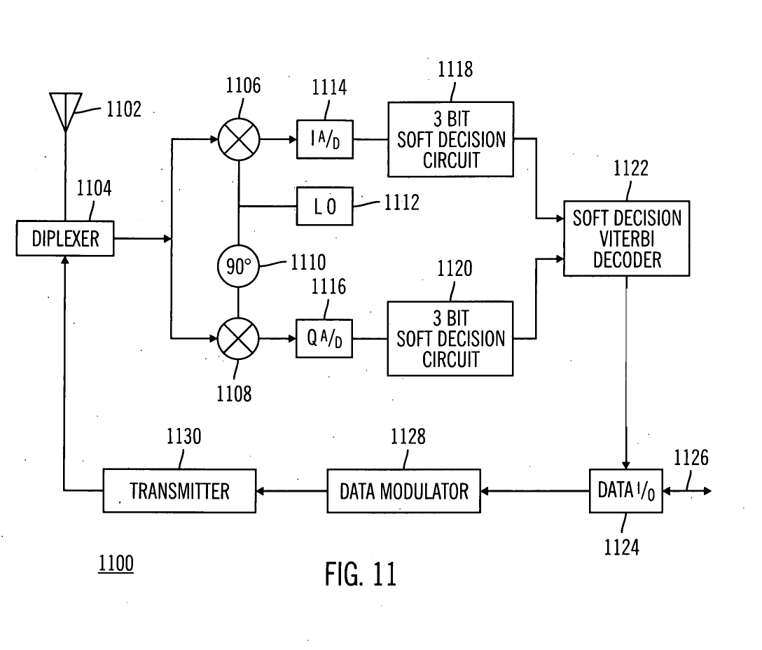

FIG. 11 illustrates an exemplary wireless data communications device 1100 in accordance with an exemplary embodiment of the present invention. The exemplary data communications device 1100 represents, for example an IEEE 802.11a compliant wireless modem or other data processing device performing wireless communications. The exemplary wireless data communications device 1100 includes an antenna 1102 that performs both RF receive and transmit functions. Antenna 1102 is electrically connected to a diplexer 1104 to allow simultaneous transmit and receive operation by the exemplary wireless data communications device 1100. Diplexer 1104 provides received RF energy to two down-converters, an In-phase down converter 1106 and a quadrature down-converter 1108. A local oscillator 1112 provides a local oscillator signal to support down conversion. The local oscillator signal is shifted ninety degrees by phase shifter 1110 to support in-phase and quadrature downconversion, as is known to ordinary practitioners in the relevant arts. The local oscillator 1112 tracks the frequency of the received signal through tracking circuits (not shown) as is well known to ordinary practitioners in the relevant arts.

The two down-converted signals, the in-phase and quadrature down-converted signals, are digitized by two analog to digital converters. An I A/D 1114 is an analog to digital converter that processes the in-phase channel or data axis, and a Q A/D 1116 is an analog to digital converter that processes the quadrature channel or data axis. The I A/D 1114 and the Q A/D 1116 produce pre-detection values from the received multiple bit QAM symbol. The I A/D 1114 produces a pre-detection value corresponding to the I axis 102 of the exemplary QAM constellation 100, and the Q A/D 1116 produces a pre-detection value that corresponds to the Q axis 104 of the exemplary QAM constellation 100. The I A/D 1114 and the Q A/D 1116 produces digitized pre-detection values that are derived from the multiple bit symbols at a symbol sampling time, as is known to ordinary practitioners in the relevant arts. The combination of local oscillator 1112, down converters In-phase down converter 1106 and quadrature down-converter 1108, and I A/D 1114 and the Q A/D 1116, make up a multiple bit symbol receiver that produces a pre-detection value of a multiple bit symbol in the exemplary embodiment.

The following description of the operation of an exemplary embodiment focuses on the processing of the pre-detection value produced by the I A/ID 1114 for the I channel axis 102. The exemplary embodiment of the present invention performs similar processing for the output of the Q A/D 1116. The processing of the Q channel axis 104 data is not described below to avoid repetition, but the description in the following discussion for the in-phase axis processing also describes the quadrature axis processing.

The output of the I A/D 1114 is provided to an I channel three-bit soft decision circuit 1118 in order to produce soft decisions for each of the three data bits that are communicated via the I axis 102 of the exemplary QAM constellation. The output of the Q A/D 1116 is similarly processed by a Q channel three bit soft decision circuit 1120. These soft decisions for the six bits conveyed by each sixty four QAM symbol are provided to a soft decision Viterbi decoder 1122 in order to produce a received data stream. The received data stream produced by the soft decision Viterbi decoder 1122 is delivered to a data Input/Ouput (I/O) circuit and is provided to other components (not shown) via a data interface 1126 as required.

Data interface 1126 also delivers data from other components that is to be transmitted by the exemplary wireless data communications device 1100. Data to be transmitted is delivered to a data modulator 1128 for encoding and modulation as required by the IEEE 802.11a standard implemented by this exemplary embodiment. The encoded and otherwise prepared signal is then provided to transmitter 1130 and diplexer 1104 for ultimate transmission via antenna 1102.

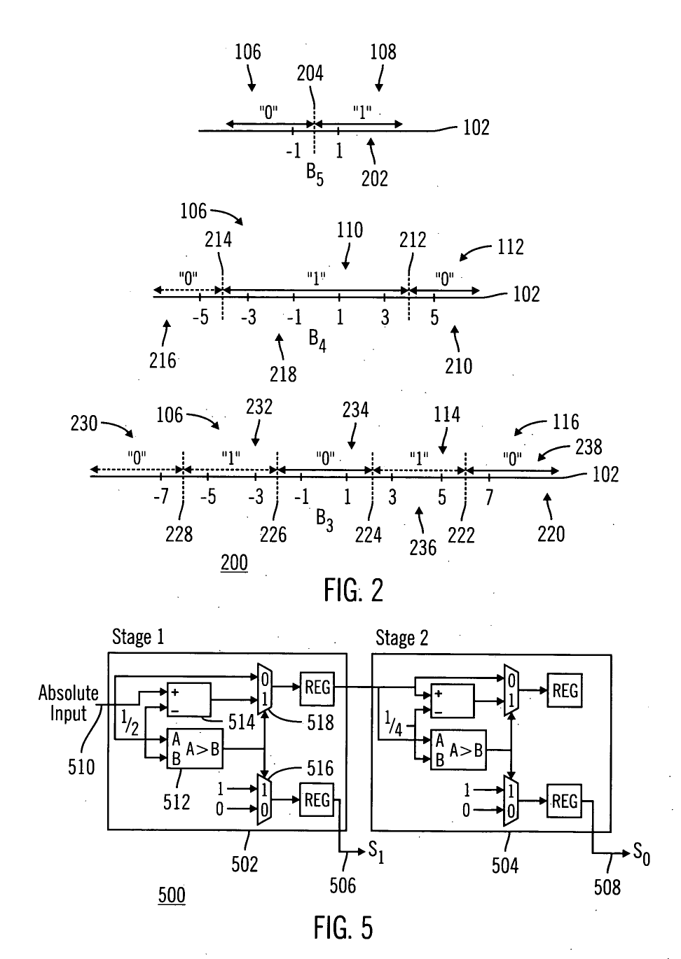

FIG. 2 illustrates decision threshold points 200 for the three data bits conveyed by one axis of the exemplary QAM constellation 100, as is used by an exemplary embodiment of the present invention. As noted above, the following discussion describes the decision threshold points 200 for the I axis pre-detection values. It is clear that the decision threshold points 200 are similar for the Q axis pre-detection values as well. The B5 I axis pre-detection values 202 illustrates values for the I axis pre-detection values along the I axis 102 that are produced by the I A/D 1114 at the symbol decision time in the exemplary embodiment. The B5 I axis pre-detection values 202 also illustrates a B5 decision point 204 that corresponds to the decision point for the sixth bit conveyed by symbols transmitted according to the QAM constellation 100. B5 I axis pre-detection values 202 is divided into two regions or bands, a “0” region 106 and a “1” region 108 along the I axis 102. These two regions are divided by the B5 decision point 204. I axis pre-detection values that are less than the B5 decision point 204 are detected as having a data bit value of zero. I axis pre-detection values that are greater than the B5 decision point 204 are detected as having a data bit value of one. A level of certainty for that detected bit is related to the distance between the pre-detection value and the B5 decision point 204. Greater certainty is associated with detected bits that have pre-detection values that have a greater distance from, i.e., values that are farther from, the decision point 204 along the I axis 102.

The B4 I axis pre-detection values 210 illustrates values for the I axis pre-detection values along the I axis 102 in relation to the two B4 detection points, a positive B4 detection point 212 and a negative B4 detection point 214. The B4 I axis pre-detection values 210 is divided into three regions or bands, a negative “0” region 216, a “1” region 218, and a positive “0” region 112 that correspond to data bit decisions for the fifth data bit, i.e., B4. The “1” region 218 is shown to include the second “0.1” region 110, which is mirrored about the zero value of the I axis 102 to form the entire “1” region 218. The negative B4 decision point 214 divides the “1” region 218 from the negative “0” region 216. The positive B4 decision point 212 divides the “1” region 218 from the positive “0” region 112 by the. The value of the B4 data bit is determined by the I axis pre-detection value, as produced by the I A/D 1114, relative to either the negative B4 decision point 214 and the positive B4 decision point 212. It is noteworthy that the B4 I axis pre-detection values 210 is symmetrical around the zero point of the I axis 102.

The B3 I axis pre-detection values 220 illustrates values for the I axis pre-detection values along the I axis 102 in relation to the four B3 detection points, a first B3 detection point 228, a second B3 detection point 226, a third B3 detection point 224, and a fourth B3 detection point 222. The B3 I axis pre-detection values 220 is divided into five regions or bands, that are divided by these four B3 detection points. A first “0” B3 band 230 is divided from a first “1” B3 band 232 by the first B3 detection point. A second “0” B3 band 234 is divided from the first “1” B3 band 232 by the second B3 detection point 226 and from a second “1” B3 band 236 by the third B3 detection point 224. A third “0” B3 band 238 is divided from the second “1” B3 band 236 by the fourth B3 detection point 222. The value of the fourth data bit, i.e., the B3 data bit, is determined by the I axis pre-detection value, as produced by the I A/D 1114, relative to these four decision points, and therefore into which B3 band the I axis pre-detection value falls. It is noteworthy that the B3 I axis pre-detection values 220 is also symmetrical around the zero point of the I axis 102 and that these two symmetrical halves have a similar configuration, although scaled, as the B4 I axis pre-detection values 210.

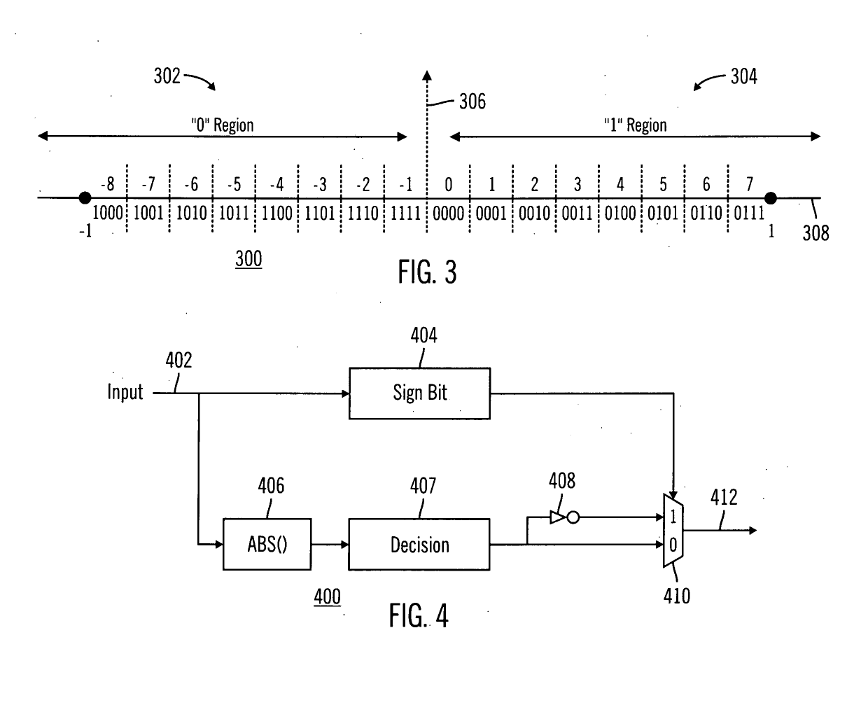

FIG. 3 illustrates a BPSK soft decision levels diagram 300 as is used by an exemplary embodiment of the present invention. The BPSK soft decision levels diagram 300 illustrates soft bit decision values that are produced by a dual-band BPSK soft demapper of the exemplary embodiment. A dual-band BPSK soft demapper is used by the exemplary embodiment implements a BPSK soft decision demapper algorithm to determine soft bit decisions for dual-band configuration data decisions, as is discussed below. The term “dual-band” in this case refers to the two data bit decision bands for the BPSK signal processed by this dual-band BPSK soft demapper. One case where a BPSK soft demapper is used in is determining soft decisions for the B5 data bit, described above. The BPSK soft decision levels diagram 300 illustrates a four bit soft decision for the single data bit conveyed by a BPSK signal. One bit in the produced soft decision indicates the detected data bit and the remaining bits indicating the confidence level for that detected data bit. The soft demapper output represented by the BPSK soft decision levels diagram 300 is in a two's complement format as is illustrated in that diagram. Note that the Q axis 306, i.e., the zero value of the I axis 308, is the separating boundary between the two bands, the “1” band 304 and the “0” band 302 in this example.

FIG. 4 illustrates a dual-band BPSK soft demapper 400 as is incorporated in the exemplary embodiment of the present invention. The exemplary embodiment of the present invention uses a dual-band BPSK soft demapper 400 that has a simplified design due to the symmetry of the soft decision levels that are to be produced, as illustrated by the BPSK soft decision levels diagram 300. The soft demapper of the exemplary embodiment processes absolute values in order to simplify hardware designs.

The exemplary dual-band BPSK soft demapper 400 accepts an input 402 that is able to be the pre-detection value for either the I axis 102 or the Q axis 104 in the case of the most significant bit for that axis, or another input as is described below. The input 402 is provided to a sign bit decision block 404, which produces the sign for the input 402. The input 402 is also provided to an absolute value processor 406 to determine the absolute value of the input 402. The absolute value is then processed by a decision circuit 407, as described below, to produce a soft decision confidence value. The soft decision confidence value is inverted by a multiple bit inverter 408 and is provided in both its original and inverted form to multiplexer 410. Based upon the value of the sign bit of the input 402, either the decision value or the inverted decision value is provided as an output 412.

FIG. 5 illustrates a BPSK soft decision circuit 500 as is incorporated into the exemplary embodiment of the present invention. This exemplary BPSK soft decision circuit 500 corresponds to the decision circuit 407 illustrated for exemplary dual-band BPSK soft demapper 400 and produces soft decision confidence for the one bit decision made for a BPSK signal. For simplicity, the BPSK soft decision circuit 500 only illustrates producing two confidence bits in addition to the data bit decision, but this design is readily extended to produce the three confidence bits described in the BPSK soft decision levels diagram 300.

As noted above, the BPSK soft decision circuit 500 of the exemplary embodiment only processes the absolute value of the input 402. This results in the most significant bit always equaling zero and therefore no processing is required for the most significant bit. The multiple bit inverter 408 converts the most significant bit based upon the detected sign produced by the sign bit detection block 404. The BPSK soft decision circuit 500 therefore only contains circuitry that determines correct values for the two other output bits, referred to as s1 506 and s0 508.

The BPSK soft decision circuit 500 is implemented with a pipelined architecture. A total of two pipelined stages are used since two confidence bits, S₁ 506 and S₀ 508, are to be determined. A first pipeline stage 502 determines the correct value for S₁ 506, and the second for S₀ 508. The first pipeline stage 502 accepts the absolute value input 510 as determined by the absolute value processing block 406. The absolute value input 510 is compared to ½ by comparator 512 and ½ is subtracted from the absolute value input 510 by difference operator 514. Output multiplexer 516 produces a value of “1” if the absolute value input 510 is larger than ½ or a “0” is produced otherwise. A second multiplexer 518 produces an output for the second pipeline stage 504 that is either the absolute value input 510 if it is less than ½ or the absolute value input 510 with ½ subtracted therefrom if it is larger than ½.

The second pipeline stage 504 performs similar processing. The second pipeline stage 504 compares the input from the first pipeline stage 502 to ¼. If the second stage input is larger than ¼, then the S₀ output 508 is set to “1,” otherwise, S₀ is set to “0.” It is clear how a third pipeline stage (not shown) that compares the output of the second pipeline stage 504 to ⅛ is able to be added to produce three decision confidence bits.

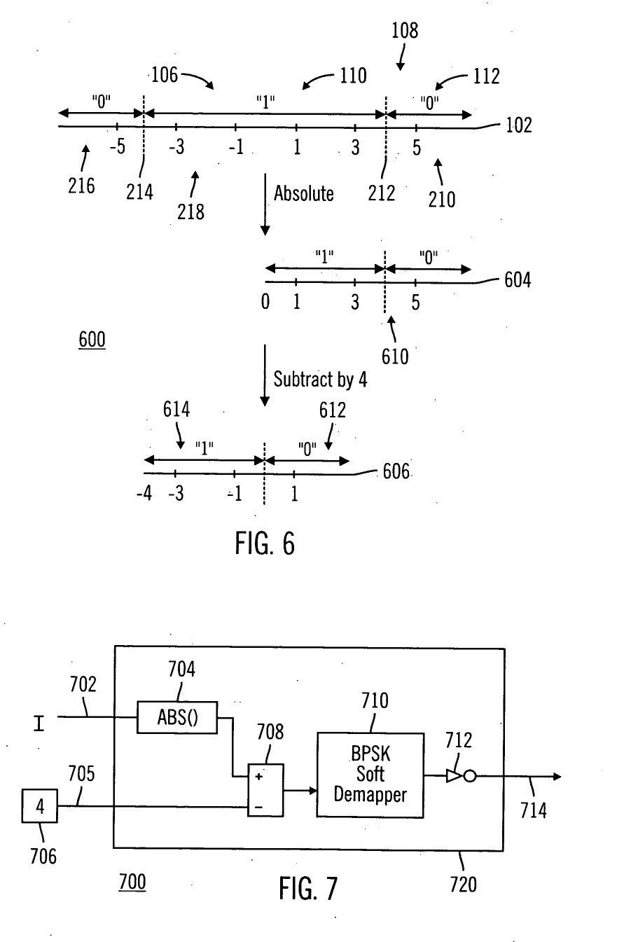

FIG. 6 illustrates tri-band decision threshold points 600 as are implemented by the exemplary embodiment of the present invention. The illustrated exemplary tri-band decision threshold points 600 show the B4 I axis pre-detection values 210 as are discussed above.

The B4 I axis pre-detection values 210 illustrate that the decision regions, i.e., the regions of the I axis 102 where a data bit value of “1” or “0” are decided, for the B4 I axis pre-detection values 210 are symmetrical about the y-axis or the zero value of the I axis 102. This feature of the Grey coding used for the exemplary QAM constellation 100 allows data bit demapping for the next significant bit to be performed with an absolute value of the input. A B4 absolute value scale 604 illustrates the effective mapping of the B4 I axis pre-detection values 210 to an absolute value scale. Determining the absolute value of the I axis pre-detection value results in the B4 absolute value scale 604 having a second bit decision point 610 with a value of four that corresponds to both the positive B4 detection point 212 and a negative B4 detection point 214 when processing the absolute value of the I axis pre-detection value.

The tri-band decision threshold points 600 further illustrate a second bit shifted I axis 606 that illustrates the B4 absolute value scale 604 shifted by an amount corresponding to the value equal to the second bit decision point, which is equal to four in this example. The shifted I axis 606 illustrates the state of the pre-detected I axis value after a shifted value is determined by the exemplary embodiment by subtracting the second bit decision point value from the pre-detected I axis value. It is noteworthy that the shifted I axis 606 depicts data bit decision regions that are similar to the dual band BPSK soft decision levels diagram 300 that is processed by the dual-band BPSK soft demapper 400 of the exemplary embodiment, except that the data bit decisions are inverted. It can be observed that in the exemplary embodiment the actual values of the BPSK symbols, which are +/−1, are not as important as producing a configuration where the data bit decision boundary is equal to 0 or a similar value for all data bit decisions. For example, the shifted I axis 606 has a data bit decision boundary of 0. This allows the transformation of a tri-band configuration into a dual-band configuration and the re-use of the dual-band BPSK soft demapper to perform the actual demapping. The exemplary embodiment of the present invention reuses the design of the dual-band soft demapper 400 to demap the tri-band data bit configuration depicted for B4 in this example.

FIG. 7 illustrates a tri-band soft decision demapper 700 according to the exemplary embodiment of the present invention. The tri-band soft decision demapper 700 of the exemplary embodiment accepts an input 702 and calculates an absolute value of the input with the absolute value operator 704. It is to be noted that the first bit, i.e., the most significant bit, has a decision threshold equal to zero in the exemplary embodiment. The calculation of the absolute value of the pre-detection value operates to determine a first value that is a distance between the first bit decision point and the pre-detection value. A subtracter 708 subtracts a shifting value 706 through a shifting value input 705. In this case of a B4 tri-band example, the shifting value corresponds to the decision point for the second bit, i.e., B4, and is equal to four. The subtracter 708 produces a normalized value in this example and delivers the normalized value to a BPSK soft demapper 710, which has been described for the dual-band BPSK soft demapper 400 above. This results in determining an inverted second bit soft decision in this example by processing the normalized value with a BPSK soft demapper algorithm. Due to the inversion of the decided data bits, and the decision regions, that are present by the shifted I axis 606, the output of the BPSK soft decision demapper 710 is inverted by the two's complement processor 712 prior to being produced as a B4 soft decision 714.

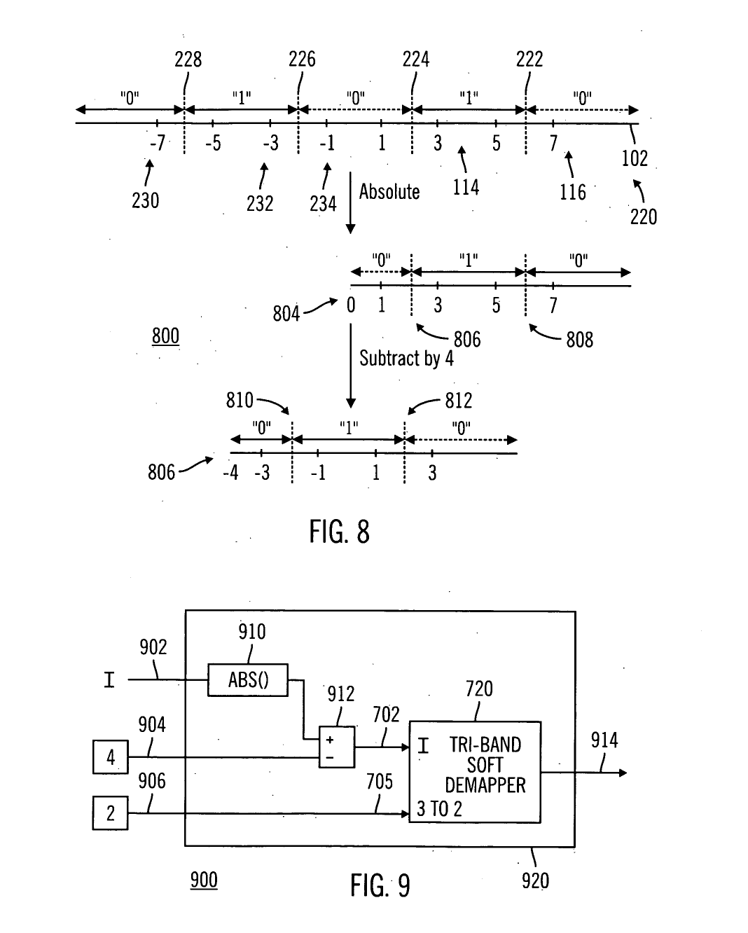

FIG. 8 illustrates penta-band decision threshold points 800 as are implemented by the exemplary embodiment of the present invention. The illustrated exemplary penta-band decision threshold points 800 show the B3 I axis pre-detection values 220 as are discussed above.

The B3 I axis pre-detection values 220 illustrate that the decision regions, i.e., the regions of the I axis 102 where a data bit value of “1” or “0” are decided, for the B3 I axis pre-detection values 220 are symmetrical about the y-axis or the zero value of the I axis 102 in this embodiment. This feature of the Gray coding used for the exemplary QAM constellation 100 allows data bit demapping for the least significant bit, i.e., bit B3, to be performed with an absolute value of the input. A B3 absolute value scale 804 illustrates the mapping of the B3 I axis pre-detection values 220 to an absolute value scale. Determining the absolute value of the I axis pre-detection value results in the B3 absolute value scale 804 having a lower B3 bit decision point 806, which has a value of two in this example, that corresponds to both the second B3 detection point 226 and third B3 detection point 224, when processing the absolute value of the I axis pre-detection value. The upper B3 bit decision point 808 similarly corresponds to both the fourth B3 detection point 222 and first B3 detection point 228.

The penta-band decision threshold points 800 further illustrates a third bit shifted absolute value I axis 806 that illustrates the B3 absolute value scale 804 shifted by an amount corresponding to the B4 decision point 212. This B4 decision point is equal to four in this example. The B3 shifted I axis 806 illustrates the state of the pre-detected I axis value after a second shifted value is determined by the exemplary embodiment by subtracting the second bit decision point value from the pre-detected I axis value. It is noteworthy that the shifted I axis 606 depicts data bit decision regions that are similar to the tri-band decision threshold points 600 discussed above, except for the scale of these pre-detected values.

FIG. 9 illustrates a penta-band soft decision demapper 900 according to the exemplary embodiment of the present invention. The penta-band soft decision demapper 900 of the exemplary embodiment accepts an input 902 that is the I axis pre-detected input in this exemplary embodiment. The penta-band soft decision demapper 900 of the exemplary embodiment calculates an absolute value of the input with the absolute value operator 910. A subtracter 912 subtracts a shifting value 904 from the absolute value produced by the absolute value operator 910. In this case of a B3 penta-band example, the shifting value corresponds to the decision point for the second bit, B4, and is equal to four. The operation of calculating the absolute value with absolute value operator 910 and subtracting the shifting value by subtractor 912 determines a second value that correspond to the distance between the first value and the second bit decision point in the exemplary embodiment. The subtractor 708 produces a normalized value 702, that corresponds to a tri-band data bit configuration, as illustrated by the third bit shifted absolute value I axis 806. The normalized value 702 is delivered to a tri-band soft demapper 720. The shifting value input 705 for this tri-band soft demapper 720 is set to a second shifting value 906, which is the distance between the second bit decision point 212 and the third bit decision point 222. The tri-band soft demapper 720 has a design similar to the tri band soft demapper described above. The tri-band soft demapper 720 has a subtracter, see subtracter 708 in FIG. 7, that determines a second normalized value by shifting the second value by an amount corresponding to the distance between the second bit decision point 212 and the third bit decision point 222. The Tri-band soft demapper further has a BPSK soft decision demapper, see BPSK soft decision demapper 710 in FIG. 7, that determines a third bit soft decision 914 by processing the second normalized value with the BPSK soft demapper algorithm.

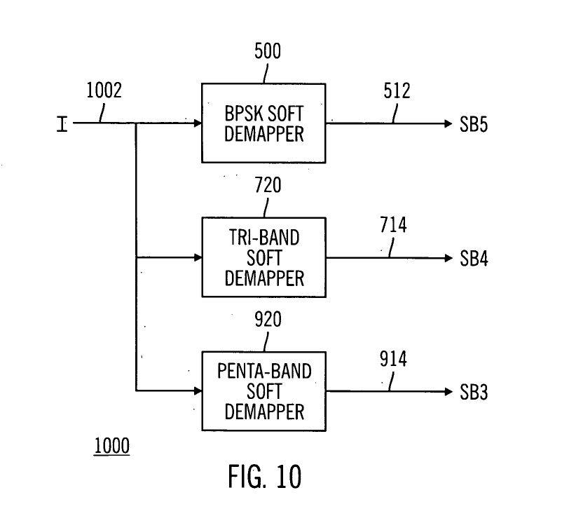

FIG. 10 illustrates a soft decision three bit I channel data detector block diagram 1000, according to the exemplary embodiment of the present invention. The soft decision three bit I channel data detector block diagram 1000 includes three soft decision circuits to process each data bit conveyed by the I axis values of the exemplary QAM constellation 100. The soft decision three bit I channel data detector block diagram 1000 depicts a circuit similar to the three bit soft decision circuit 1118, described above, in the exemplary embodiment. The soft decision three bit I channel data detector block diagram 1000 illustrates that an I axis pre-detection value 1002 is accepted as an input and supplied in parallel to all three soft decision circuits. A BPSK soft demapper 500 produces the most significant data bit soft decision SB₅ 412, a tri-band soft demapper 720 produces a second significant bit soft decision SB₄ 714 and a penta-band soft demapper 920 produces a least significant bit soft decision SB₃ 914.

The exemplary embodiment of the present invention processes the pre-detected value 1002 by the three soft decision circuits in a parallel fashion to improve processing speed. Such embodiments reuse circuit designs for the BPSK soft decision demapper and other components, as described above. Further embodiments of the present invention perform soft decisions for multiple bits in a serial fashion and incorporate one or a reduced number BPSK soft decision demappers.

The above describe processing is able to be expanded to processing symbols that communicate an arbitrary number of bits in a processed I and/or Q axis. In the case of QPSK, the number of data bits conveyed by each of the I and Q axes, referred to as “M,” has M=1. In the case of a QAM 16 constellation, where M=2, maximum number of bands along each axis for the least significant bit is three. Denoting NBₘ to represent the maximum number of data bit decision bands for a 2²*^{m} point constellation, NBₘ and NBₘ₋₁ are calculated by the following equation with an initial condition of NB₁=2:
NB ₘ=2*NB ₘ₋₁ for m≧2

Embodiments of the present invention use this relationship to systematically reduce any higher order 2²*^{M} constellation down to the simple dual-band configuration that is processed as described above. Solving the previous recursive equation, we can relate NBₘ and m with the following:
NB ₘ=2^{m-1}+1 for m≧1

The number of transformations required to reduce a high order constellation to the dual-band configuration is determined as follows. Using the QAM64 example shown above, we note that B5 is already in a dual-band configuration, so it doesn't need any additional transformation. We then note that B4 is in a tri-band configuration, therefore requiring one transformation to bring the B4 setup into a dual-band one. The B3 is shown to require two steps to transform into a dual-band configuration, one from penta to tri band and another transformation from tri to dual band. Therefore the total number of transformation needed for the I-component conveyed bits is given by 1+2=3. For the Q-component bits, the same number of steps is needed, which brings the total number of transformations to 3+3=6. In general, for a 2²*^{m} constellation, m bits are conveyed by the I-component. The total number of transformations to process of the I-bits is:

$${\sum }_{i = 1}^{m - 1} i = \frac{m * ( m - 1 )}{2}$$

With the equal number of transformations needed for the Q-bits, the total number of transformations becomes m*(m-1).

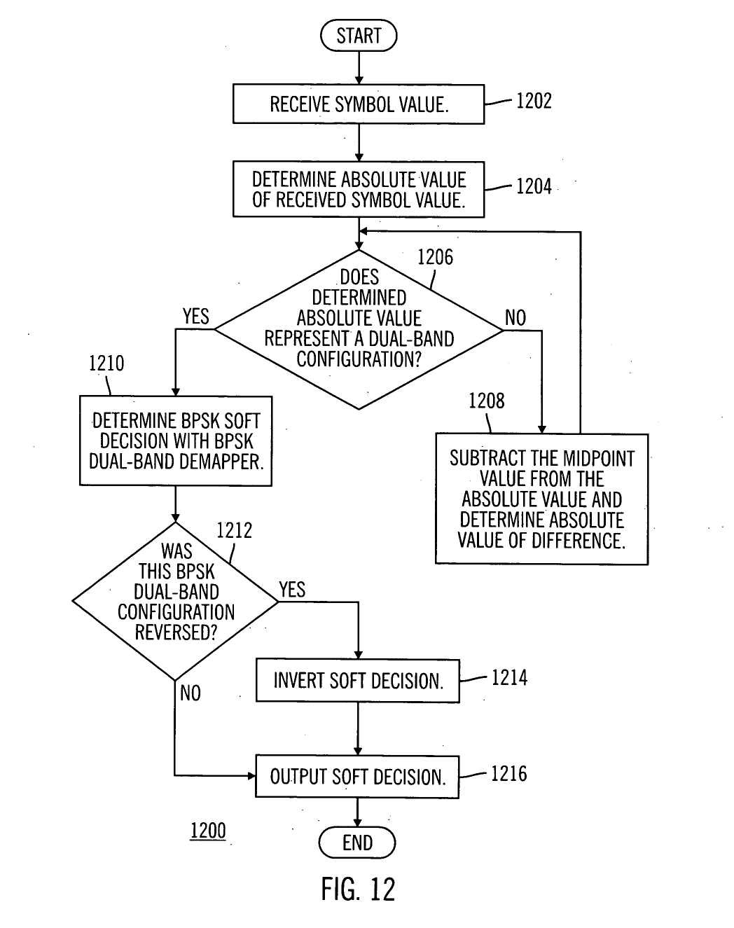

FIG. 12 illustrates an arbitrary bit soft decision processing flow 1200 as is performed by a further exemplary embodiment of the present invention that processes multiple bit symbols that convey more than three data bits along one or both of the I and Q axes of the pre-detected symbol. The arbitrary bit soft decision processing flow 1200 processes values for either an I or Q channel, with similar processing for both channels. The arbitrary bit soft decision processing flow 1200 produces an Nth bit that is conveyed along the processed axis of the received signal.

The arbitrary bit soft decision processing flow 1200 begins by receiving, at step 1202, the symbol value for the axis or channel being processed. The processing continues by determining, at step 1204, the absolute value of the received symbol value. The processing then continues by determining, at step 1206, if the band configuration, as described above, of the determined absolute value is in a dual-ban mode. If the determined absolute value does not represent a dual-band configuration, the resulting configuration will have an odd number of bands. In this case, the processing subtracts, at step 1208, the mid-point value of the possible range of values for the determined absolute value and determines, also at step 1208, the absolute value of that difference. After performing this subtraction, the processing returns to determining, at step 1206, if the determined absolute value represents a dual band configuration.

If the determined absolute value was determined to represent a dual-band configuration, the processing performs, at step 1210, the BPSK dual-band demapper processing described above. The processing then determines, at step 1212, if this BPSK dual-band configuration was reversed. As described above, some multi-level bit decision bands are reversed in polarity when they are transformed to the BPSK dual-band configuration. If the BPSK dual-band configuration was determined to be reversed, the processing inverts, at step 1214, the determined soft decision. The processing then outputs, at step 1216, the soft decision.

The exemplary embodiments of the present invention advantageously simplify the process of soft demapper design and essentially reduce a complex, higher constellation problem into a simple BPSK soft demapper problem. The core engine in these exemplary embodiments is a dual-band, i.e., a BPSK, demapper, design efforts can be directed to optimizing the BPSK demapper relative to desired criteria, e.g. performance, area, or power consumption. The application of embodiments of the present invention is particularly useful in constructing demappers for Grey encoded symbols.

The present invention can be realized in hardware, software, or a combination of hardware and software. A system according to an exemplary embodiment of the present invention can be realized in a centralized fashion in one computer system, or in a distributed fashion where different elements are spread across several interconnected computer systems. Any kind of computer system—or other apparatus adapted for carrying out the methods described herein—is suited. A typical combination of hardware and software could be a general purpose computer system with a computer program that, when being loaded and executed, controls the computer system such that it carries out the methods described herein.

The present invention can also be embedded in a computer program product, which comprises all the features enabling the implementation of the methods described herein, and which—when loaded in a computer system—is able to carry out these methods. Computer program means or computer program in the present context mean any expression, in any language, code or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least one computer readable medium that allows a the computer to read data, instructions, messages or message packets, and other computer readable information. The computer readable medium may include non-volatile memory, such as ROM, Flash memory, Disk drive memory, CD-ROM, and other permanent storage. Additionally, a computer medium may include, for example, volatile storage such as RAM, buffers, cache memory, and network circuits. Furthermore, the computer readable medium may comprise computer readable information in a transitory state medium such as a network link and/or a network interface, including a wired network or a wireless network, that allow a computer to read such computer readable information.

The terms “a” or “an”, as used herein, are defined as one or more than one. The term plurality, as used herein, is defined as two or more than two. The term another, as used herein, is defined as at least a second or more. The terms including and having, as used herein, are defined as comprising (i.e., open language). The term coupled, as used herein, is defined as connected, although not necessarily directly, and not necessarily mechanically.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method for determining soft decisions, the method comprising:
determining a first value representing a distance between a first bit decision point and a pre-detection value of a multiple bit symbol, the multiple bit symbol representing at least a first bit and a second bit;
determining a normalized value by shifting the first value by an amount corresponding to a second bit decision point;
determining an inverted second bit soft decision by processing the normalized value with a BPSK soft demapper algorithm; and
producing a second bit soft decision by inverting the inverted second bit soft decision value.

2. The method according to claim 1, wherein the multiple bit symbol further represents at least a third bit, the method further comprising:
determining a second value that corresponds to a distance between the first value and the second bit decision point;
determining a second normalized value by shifting the second value by an amount corresponding to a distance between the second bit decision point and a third bit decision point; and
determining a third bit soft decision by processing the second normalized value with the BPSK soft demapper algorithm.

3. The method according to claim 2, wherein the multiple bit symbol represents at least N bits, the method further comprising:
iteratively determining a respective bit value for respective bits between and including a fourth bit and an Nth bit, the respective bit value corresponding to a distance between a previous respective bit value and a distance between a respective bit decision point and a preceding respective bit decision point, the previous respective bit value being determined for a data bit immediately preceding the respective bit and the preceding respective bit decision point being a decision point for the data bit immediately preceding the respective bit;
shifting an N^{th} bit value by an amount corresponding to a distance between an (N−1) ^{th} bit decision point and an N^{th} bit decision point;
processing the normalized Nth bit value with the BPSK soft demapper algorithm to determine a preliminary N^{th} bit soft decision;
determining if N is odd; and
producing an Nth bit soft decision by, if N is odd, producing an inverted value of the preliminary soft decision, and, if N is even, producing the preliminary soft decision.

4. The method according to claim 1, wherein the first bit decision point is zero and the determining the first value comprises calculating an absolute value for the pre-detection value.

5. The method according to claim 1, wherein the second bit decision point is a midpoint value of the pre-detection value for the second bit.

6. The method according to claim 1, wherein at least the first bit and the second bit are encoded into the multiple bit symbol with Gray encoding so as to allow the soft decision for the first data bit and the soft decision for the second data bit to directly correspond to two data bits of the at least two data bits.

7. The method according to claim 1, wherein the shifting the first value is performed by subtracting a value of the second bit decision point from the first distance.

8. A soft decision demapper comprising:
a first magnitude determination circuit that determines a first value representing a distance between a first bit decision point and a pre-detection value of a multiple bit symbol, the multiple bit symbol representing at least a first bit and a second bit;
a value normalizer that determines a normalized value by shifting the first value by an amount corresponding to a second bit decision point;
at least one BPSK soft demapper that determines an inverted second bit soft decision by processing the normalized value; and
a data inverter that produces a second bit soft decision by inverting the inverted second bit soft decision value.

9. The soft decision demapper according to claim 8, wherein the multiple bit symbol further represents at least a third bit, the method further comprising:
a first magnitude determination circuit that determines a second value that corresponds to a distance between the first value and the second bit decision point;
a second normalizer that determines a second normalized value by shifting the second value by an amount corresponding to a distance between the second bit decision point and a third bit decision point; and
wherein the at least one BPSK soft demapper further determines a third bit soft decision by processing the second normalized value.

10. The soft decision demapper according to claim 9, wherein the multiple bit symbol represents at least N bits, the method further comprising:
an iterative magnitude determination circuit that iteratively determines a respective bit value for respective bits between and including a fourth bit and an Nth bit, the respective bit value corresponding to a distance between a previous respective bit value and a distance between a respective bit decision point and a preceding respective bit decision point, the previous respective bit value being determined for a data bit immediately preceding the respective bit and the preceding respective bit decision point being a decision point for the data bit immediately preceding the respective bit;
a third normalizer that shifts an N^{th} bit value by an amount corresponding to a distance between an (N−1)^{th} bit decision point and an Nth bit decision point, and wherein the at least one BPSK soft decision demapper processes the normalized Nth bit value to determine a preliminary N^{th} bit soft decision; and
a second data inverter that produces an Nth bit soft decision by, if N is odd, producing an inverted value of the preliminary soft decision, and, if N is even, producing the preliminary soft decision.

11. The soft decision demapper according to claim 8, wherein the second bit decision point is a midpoint value of the pre-detection value for the second bit.

12. The soft decision demapper according to claim 8, wherein at least the first bit and the second bit are encoded into the multiple bit symbol with Gray encoding so as to allow the soft decision for the first data bit and the soft decision for the second data bit to directly correspond to two data bits of the at least two data bits.

13. The soft decision demapper according to claim 8, wherein the value normalizer comprises a subtracter that subtracts a value of the second bit decision point from the first distance.

14. A computer program product comprising machine readable instructions for determining soft decisions, the machine readable instructions comprising instructions for:
determining a first value representing a distance between a first bit decision point and a pre-detection value of a multiple bit symbol, the multiple bit symbol representing at least a first bit and a second bit;
determining a normalized value by shifting the first value by an amount corresponding to a second bit decision point;
determining an inverted second bit soft decision by processing the normalized value with a BPSK soft demapper algorithm; and
producing a second bit soft decision by inverting the inverted second bit soft decision value.

15. The computer program product according to claim 14, wherein the multiple bit symbol further represents at least a third bit, the computer program product further comprising instruction for:
determining a second value that corresponds to a distance between the first value and the second bit decision point;
determining a second normalized value by shifting the second value by an amount corresponding to a distance between the second bit decision point and a third bit decision point; and
determining a third bit soft decision by processing the second normalized value with the BPSK soft demapper algorithm.

16. The computer program product according to claim 15, wherein the multiple bit symbol represents at least N bits, the computer program product further comprising instruction for:
iteratively determining a respective bit value for respective bits between and including a fourth bit and an Nth bit, the respective bit value corresponding to a distance between a previous respective bit value and a distance between a respective bit decision point and a preceding respective bit decision point, the previous respective bit value being determined for a data bit immediately preceding the respective bit and the preceding respective bit decision point being a decision point for the data bit immediately preceding the respective bit;
shifting an Nth bit value by an amount corresponding to a distance between an (N−1)^{th} bit decision point and an Nth bit decision point;
processing the normalized Nth bit value with the BPSK soft demapper algorithm to determine a preliminary N^{th} bit soft decision;
determining if N is odd; and
producing an Nth bit soft decision by, if N is odd, producing an inverted value of the preliminary soft decision, and, if N is even, producing the preliminary soft decision.

17. A communications device, comprising:
a multiple bit symbol receiver that produces a pre-detection value of a multiple bit symbol;
a first magnitude determination circuit that determines a first value representing a distance between a first bit decision point and a pre-detection value of a multiple bit symbol, the multiple bit symbol representing at least a first bit and a second bit;
a value normalizer that determines a normalized value by shifting the first value by an amount corresponding to a second bit decision point;
at least one BPSK soft demapper that determines an inverted second bit soft decision by processing the normalized value; and
a data inverter that produces a second bit soft decision by inverting the inverted second bit soft decision value.
